(19) United States
(12) Patent Application Publication
(10) Pub. No.: US 2015/0316590 A1
(43) Pub. Date: Nov. 5, 2015

(54) LOW ELECTROMAGNETIC INTERFERENCE VOLTAGE MEASUREMENT SYSTEM

(71) Applicant: The United States of America as represented by the Secretary of the Navy, Crane, IN (US)

(72) Inventors: Bradley F. Eid, Greenwood, IN (US); Nixon A. Pendergrass, Nashville, IN (US)

(21) Appl. No.: 14/676,810

(22) Filed: Apr. 1, 2015

Related U.S. Application Data
(60) Provisional application No. 61/973,310, filed on Apr. 1, 2014.

(51) Int. Cl. G01R 19/25

(52) U.S. Cl. CPC G01R 19/25

(57) ABSTRACT

A low electromagnetic interference (“EMI”) voltage measurement system may include a voltage-digitizing transmission module configured to digitize multiple input voltages and digitally transmit values, a fiber optic cable configured to transmit values from the transmission module to a receiver module and from the receiver module to a personal computer having recording software. Various methods are also provided including steps associated with multiplexing voltage to fiber-optical conversion.

### CROSS-REFERENCE TO RELATED APPLICATION

This application claims priority to U.S. Provisional Application Ser. No. 61/973,310 filed on Apr. 1, 2014 the disclosure of which is expressly incorporated herein by reference.

### STATEMENT REGARDING FEDERALLY SPONSORED RESEARCH OR DEVELOPMENT

The invention described herein was made in the performance of official duties by employees of the Department of the Navy and may be manufactured, used and licensed by or for the United States Government for any governmental purpose without payment of any royalties thereon. This invention (Navy Case 103,205) is assigned to the United States Government and is available for licensing for commercial purposes. Licensing and technical inquiries may be directed to the Technology Transfer Office, Naval Surface Warfare Center Crane, email: Cran_CTO@navy.mil.

### FIELD OF THE DISCLOSURE

The present disclosure generally relates to an apparatus and method for a low electromagnetic interference (EMI) voltage measurement system and more particularly to a system for digitizing, transmitting, receiving and recording voltages to a computing device.

### BACKGROUND AND SUMMARY OF THE INVENTION

Many commercial off-the-shelf (COTS) solutions include capabilities which allow digitizing and recording of analog voltage values. However, many of these systems are unable to meet cost and environmental requirements while still meeting desired performance characteristics. Likewise, some of these systems may be able to meet the cost or environmental objectives of the design, but not both. Thus, no current prior art or COTS low EMI voltage measurement system exists which meets all three design objectives. Accordingly, a need exists for an improved method and apparatus for digitizing, transmitting, receiving, and recording voltages to an electrically isolated recording device, which is physically distant from a voltage source or a device under test (DUT). Accordingly, there is also a need for a low EMI voltage measurement systems wherein the voltage measurements are made in a manner that minimizes changes to the electromagnetic fields near a radio frequency (RF) device under test.

In one embodiment of the present disclosure a low electromagnetic interference (“EMI”) voltage measurement system is provided comprising an input selection device configured to receive a plurality of analog voltage signals and output one of the plurality of analog voltage signals; a converter circuit coupled to the input selection device, the converter circuit configured to convert at least a first analog voltage signal to a first digital signal and convert a second analog voltage signal to a second digital signal; a clock circuit configured to output a clock signal to cause the input selection device to output one of the plurality of analog voltage signals; a counter circuit coupled to the input selection device, the counter circuit configured to receive the clock signal and to provide input selection logic to the input selection device in response to receiving the clock signal; a fiber optic transmitter coupled to the converter circuit and configured to transmit the first digital signal to a fiber optic receiver and transmit the second digital signal to the fiber optic receiver; and a receiver circuit configured to receive at least the transmitted first digital signal and receive the transmitted second digital signal, the receiver circuit including a latching device configured to latch the first digital signal and to latch the second digital signal and in response to latching a predetermined threshold amount of digital signals, the receiver circuit transmits the latched digital signals to a computing device; wherein the clock signal is based on the discharge rate of a first voltage storage device, the clock signal occurring at a frequency that is below a predetermined threshold frequency such that EMI does not alter operation of a device under test adjacent the low EMI voltage measurement system.

In another embodiment of the present disclosure a method in a low EMI voltage measurement system is provided comprising receiving, by an input selection device, a plurality of analog voltage signals and outputting one of the plurality of analog voltage signals; converting, by a converter circuit, at least a first analog voltage signal to a first digital signal and a second analog voltage signal to a second digital signal; providing, by a clock circuit, a clock signal to a counter circuit configured to output input selection logic wherein the clock signal is based on the discharge rate of a first voltage storage device, the clock signal occurring at a frequency that is below a predetermined threshold frequency such that EMI does not alter operation of a device under test adjacent the low EMI voltage measurement system; providing, by a counter circuit, input selection logic to the input selection device in response to the counter circuit receiving the clock signal wherein the input selection logic causes the input selection device to output one of the plurality of analog voltage signals; transmitting, by a fiber optic transmitter, the first digital signal to a fiber optic receiver and the second digital signal to the fiber optic receiver; receiving, by a receiver circuit, at least the transmitted first digital signal and the transmitted second signal wherein the receiver circuit includes a latching device configured to latch the first digital signal and to latch the second digital signal; and transmitting, by the receiver circuit, at least the latched first digital signal and the latched second digital signal in response to the latching device latching a predetermined threshold amount of digital signals wherein the transmitted latched digital signals are received by a computing device.

In yet another embodiment of the present disclosure a low EMI voltage measurement system is provided comprising an input selection device configured to receive a plurality of analog voltage signals and output one of the plurality of analog voltage signals; a transmitter module coupled to the input selection device, the transmitter module configured to convert an analog voltage signal to a digital signal and transmit the digital signal; a receiver module coupled to the transmitter module and configured to receive the digital signal, the receiver module including a latching device configured to latch the digital signal and in response to latching a predetermined threshold amount of digital signals, the receiver module transmits the latched digital signals to a computing device; and a clock circuit coupled to the input selection device and configured to output a clock signal to cause the input selection device to output one of the plurality of analog voltage signals, wherein the clock signal occurs at a frequency that is below a predetermined threshold frequency such that EMI does not alter operation of a device under test adjacent the low EMI voltage measurement system.

In yet another embodiment of the present disclosure a low EMI voltage measurement system is provided comprising an input selection device configured to receive a plurality of analog voltage signals and output one of the plurality of analog voltage signals; a converter circuit coupled to the input selection device, the converter circuit configured to convert at least a first analog voltage signal to a first digital signal, convert a second analog voltage signal to a second digital signal, and output a clock signal; a counter circuit coupled to the input selection device, the counter circuit configured to receive the clock signal and to provide input selection logic to the input selection device in response to receiving the clock signal; a logic circuit coupled to the converter circuit, the logic circuit configured to at least invert the first digital signal and invert the second digital signal; a fiber optic transmitter coupled to the logic circuit and configured to transmit the first digital signal to a fiber optic receiver and transmit the second digital signal to the fiber optic receiver; and a receiver circuit configured to receive at least the transmitted first digital signal and receive the transmitted second digital signal, the receiver circuit including a latching device configured to latch the first digital signal and to latch the second digital signal and in response to latching a predetermined amount of digital signals, the receiver circuit transmits the latched digital signals to a computing device; wherein the clock signal is based on the discharge rate of a first voltage storage device, the clock signal occurring at a frequency that is below a predetermined threshold frequency such that EMI does not alter operation of a device under test adjacent the low EMI voltage measurement system.

### BRIEF DESCRIPTION OF THE DRAWINGS

The detailed description of the drawings particularly refers to the accompanying figures in which:

FIG. 1 is an exemplary block diagram of a low electromagnetic interference (EMI) voltage measurement system in accordance with the present disclosure.

FIG. 2A shows an exemplary multiplexed pulse width modulation conversion with a dithered clock in accordance with the present disclosure.

FIG. 2B shows an exemplary multiplexed pulse width modulation conversion with analog signal feedback in accordance with the present disclosure.

FIG. 3 shows an exemplary transmitter module schematic in accordance with the present disclosure.

FIG. 4 shows an exemplary receiver module schematic in accordance with the present disclosure.

FIG. 5 shows an exemplary data stream unpacking algorithm in accordance with the present disclosure.

FIG. 6 shows a table providing an exemplary transmission frame in accordance with the present disclosure.

FIG. 7 shows a flow diagram of an exemplary method of the low EMI voltage measurement system of FIGS. 1-4.

FIGS. 8A, 8B, 8C, 8D, 8E, and 8F show source code which may be used to develop one or more software applications or software programs to accomplish one or more functions of the low EMI voltage measurement system of FIGS. 1-7.

### DETAILED DESCRIPTION OF THE DRAWINGS

The embodiments of the invention described herein are not intended to be exhaustive or to limit the invention to precise forms disclosed. Rather, the embodiments selected for description have been chosen to enable one skilled in the art to practice the invention.

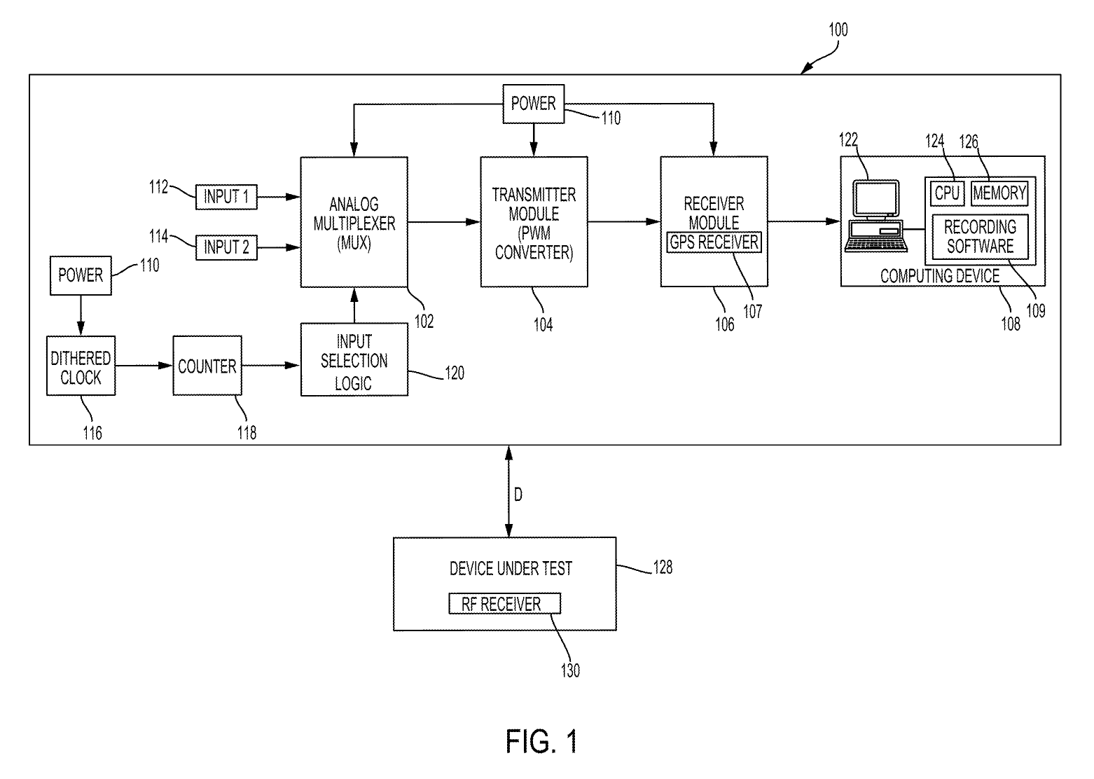

FIG. 1 is an exemplary block diagram of low electromagnetic interference (EMI) voltage measurement system 100 (hereinafter “system 100”). System 100 generally provides an exemplary multiplexed pulse width modulated (“PWM”) conversion system having a dithered clock algorithm for digitizing multiple voltages without the use of a stable clock. System 100 includes analog multiplexer 102 (hereinafter “MUX 102”), transmitter module 104, receiver module 106, computing device 108, power 110, first input 112, second input 114, and input select logic 120, dithered clock 116, device under test 128 (hereinafter “DUT 128”) and counter 118. In one embodiment of the present disclosure first input 112 includes one or more measured analog voltage signals each signal corresponding to an analog voltage value and second input 114 includes one or more analog reference voltage signals each signal corresponding to an analog voltage value. As is known in the art, MUX 102 may be designed or configured to function as an input selection device configured to receive a plurality of measured analog voltage signals from first input 112 and a plurality of reference analog voltage signals from second input 114 and output one of the plurality of analog voltage signals. As is also known in the art, MUX 102 may also be designed such that input selection logic comprising one or more bits or a discrete signal is also provided as an input to MUX 102 such that the input selection logic causes MUX 102 to output an analog voltage signal corresponding to a particular input pin.

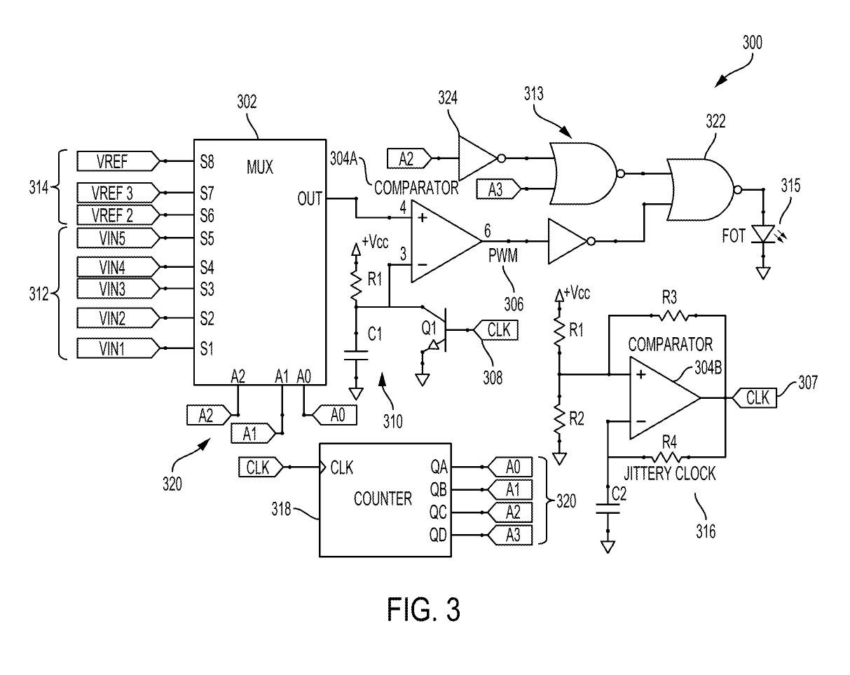

In the illustrative embodiment of FIG. 1, transmitter module 104 is coupled to MUX 102 and is an exemplary PWM converter circuit configured to convert at least a first analog voltage signal to a first digital data signal and convert a second analog voltage signal to a second digital data signal and transmit the first and second digital data signals via, for example, a fiber optic transmitter. Transmitter module 104 is described in further detail in the disclosed embodiment of FIG. 3. Receiver module 106 is coupled to transmitter module 104 and includes global positioning system (“GPS”) receiver. Receiver module 106 may include a receiver circuit (not shown) configured to receive at least the transmitted first digital signal provided by transmitter module 104 and receive the transmitted second digital signal provided by transmitter module 104. The receiver circuit may be further configured such that in response to receiving a predetermined threshold amount of digital signals, the receiver circuit transmits the digital signals to a computing device such as computing device 108. Receiver module 106 may further illustratively include a global position system (“GPS”) receiver 107 coupled to the receiver circuit. As is known in the art, GPS receiver 107 may be configured to provide universal-time-stamping of the digital signals transmitted by transmitter module 104 and received by receiver module 106. Thus, GPS receiver 107 is configured to allow synchronized receipt of the one or more analog voltage values corresponding to the digital signals.

Computing device 108 illustratively includes a personal computer communicably coupled to a monitor/display 122 operative to display data accessible by the personal computer. Computing device 108 further includes a processor 124 such as a computer processing unit (“CPU”) and at least one memory module 126. Exemplary personal computers include various commercially available standard desktop computing systems such as Dell desktop computers. In one embodiment of the present disclosure, computing device 108 includes recording software 109 configured to record one or more digital signals corresponding to the one or more analog voltage signals, and in response to recording, storing, the one or more digital signals in memory 126.

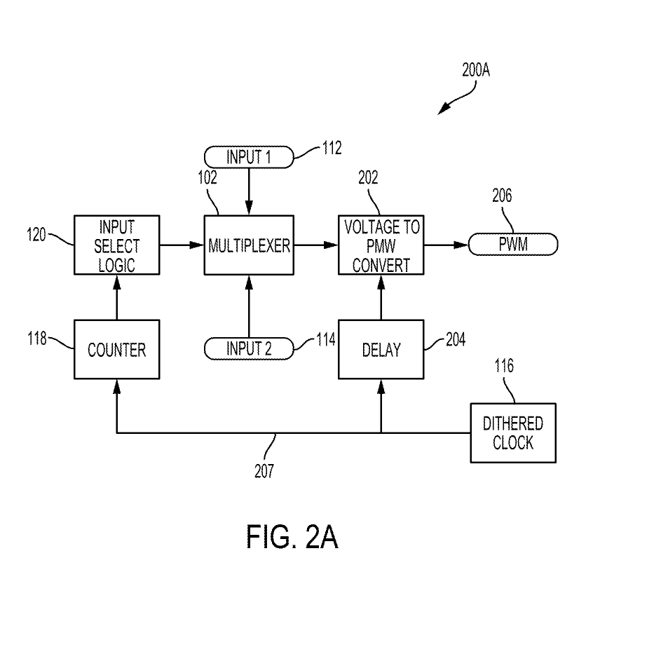

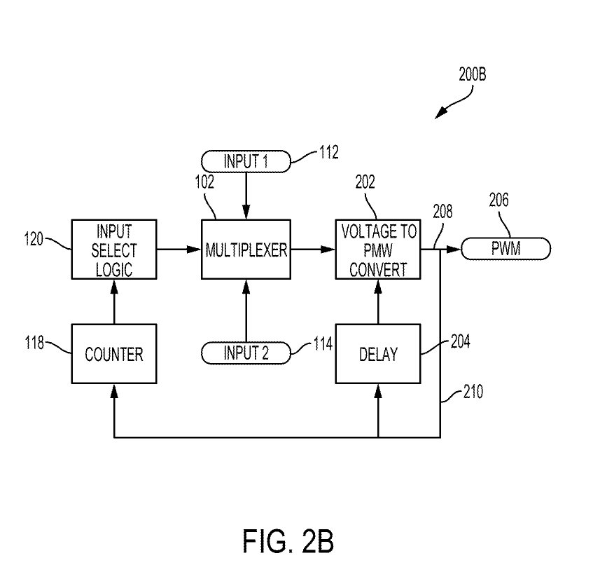

In various embodiments of the present disclosure power 110 provides the necessary direct current (“DC”) voltage to power the various components of system 100. In one embodiment, power 110 provides a voltage range of 5 VDC to 12 VDC. In the illustrative embodiment of FIG. 1, power 110 provides at least 5 VDC to MUX 102, to transmitter module 104, to receiver module 106, and to dithered clock 116. Additionally, in the illustrative embodiment of FIG. 1, dithered clock 116 may be a conventional clock circuit configured to output a clock signal wherein the clock signal ultimately causes MUX 102 to output one of the plurality of measured or reference analog voltage signals. Use of dithered or jittery clock 116 spreads the spectrum of any stray radiated emissions, moreover if the analog voltage input signals provided to MUX 102 are noisy or have a random time-varying component than dithered clock 116 could be removed entirely and a PWM clock signal may be used to strobe the next conversion as shown in the disclosed embodiment of FIG. 2B. Counter circuit 118 may be coupled to dithered clock 116 and configured to output one or more bits or a discrete signal which function as input selection logic 120. As indicated above, the discrete signal of input selection logic 120 are provided as inputs to MUX 102 such that input selection logic 120 causes MUX 102 to output an analog voltage signal corresponding to a particular input pin of MUX 102. As discussed in greater detail in the disclosed embodiment of FIG. 3, MUX 102 may be designed to include a plurality of input pins wherein each input pin receives a particular analog voltage input signal. System 100 is operable within a temperature range of −20° C. to +60° C. and includes a voltage measurement accuracy of less than 1 OmV and operates based on a direct current (DC) supply voltage ranging from 5 VDC to 12 VDC.

In various embodiments of the present disclosure, DUT 128 includes a radio frequency “RF” receiver 130 configured to operate at least in response to receiving an RF signal having a particular frequency. As described in further detail below, system 100 may be positioned adjacent to or in close proximity with DUT 128 wherein the distance “D” between system 100 and DUT 128 may range from 6 inches or higher. In one embodiment, system 100 is positioned in close proximity to DUT 128 such that near field communication testing maybe accomplished. System 100 may be configured to operate, based on a clock signal frequency that is distinct from the operating frequency of RF receiver 130 of DUT 128. In an alternative embodiment of the present disclosure, system 100 may be configured to automatically detect the operating frequency of DUT 128. In this embodiment, system 100 may be further configured to determine the operating frequency of DUT 128 and in response to determining this operating frequency automatically adjust the clock signal generated by dithered clock 116.

In one embodiment system 100 includes software within computing system 108 which enables system 100 to perform the automated steps indicated above. For example, in one embodiment system 100 includes a processor 124, a non-transitory machine instruction storage section 126 configured to store a plurality of non-transitory machine readable instructions operable to control processor 124 and control a plurality of other elements including system 100. The plurality of machine readable instructions may comprise a first plurality of machine readable instructions for operating a transceiver, DUT 128 and system 100 to determine one or more operating frequencies of at least an electromagnetic receiver such as RF receiver 130 within DUT 128, a second plurality of machine readable instructions for saving said operating frequencies on said recording medium such as memory 126 and configuring a clock such as dithered clock 116 to operate at a frequency other than said one or more operating frequencies.

FIG. 2A is an exemplary block diagram of transmitter module 104 including multiplexed pulse width modulation (PWM) conversion with dithered clock. In the illustrative embodiment of FIG. 2A, system 200A includes substantially the same components as system 100 and further shows voltage to PWM converter 202, PWM signal 206 and delay module 204. In this embodiment dithered clock 116 provides a clock signal 207 to delay module 204 as well as counter 118. Delay module 204 includes a standard delay circuit (not shown) configured to delay clock signal 207 provided by dithered clock 116 such that, for example, MUX 102 receives clock signal 207 at a first time period and voltage to PWM converter 202 receives clock signal 207 at a second time period. Delay module 204 ensures correct operation of the multiplexed PWM conversion because providing clock signal 207 to MUX 102 first allows the analog voltage signal sufficient time to move along the signal path to the input of voltage to PWM converter 202. Thus, MUX 102 outputs the analog voltage signal before PWM converter 202 attempts to convert the analog signal to a digital signal such as PWM signal 206.

FIG. 2B shows an exemplary multiplexed PWM conversion with PWM signal feedback. In the illustrative embodiment of FIG. 2B, system 200B includes substantially the same components as system 100 and system 200A and further shows and clock signal 208 moving along feedback path 210 to delay module 204 and counter 118. As described in further detail in the disclosed embodiment of FIG. 3, voltage to PWM converter 202 includes a resistor-capacitor (“RC”) circuit configured to provide a clock signal such as clock signal 208. In the illustrative embodiment of FIG. 2B, the RC circuit also provides clock signal 208 to delay module 204 as well as counter 118. As indicated above, delay module 204 includes a standard delay circuit (not shown) configured to delay clock signal 208 provided by the RC circuit such that, for example, MUX 102 receives clock signal 208 at a first time period and voltage to PWM converter 202 receives the clock signal at a second time period.

FIG. 3 is an exemplary transmitter module schematic. Transmitter schematic 300 includes first input 312, second input 314, MUX 302, input select logic 320, counter 318, voltage to PWM converter circuit 310 (hereinafter “PWM circuit 310”), logic circuit 313, fiber optic transmitter (“FOT”) 315, comparator 304A and 304B, and dithered/jittery clock 316. Transmitter schematic 300 further includes PWM signal 306 provided by PWM circuit 310, clock signal 307 also provided PWM circuit 310, and clock signal 308 provided jittery clock 316. In the illustrative embodiment of FIG. 3, transmitter schematic 300 provides a realization of a transmission module 104 and may also be referred to as multiplexer or MUX board or transmitter circuit 300. MUX 302 is an analog multiplexer configured to interleave analog voltage signals prior to digitization and transmission. In one illustrative embodiment, up to eight analog voltage signals are multiplexed by MUX 302 and later digitized by PWM circuit 310. PWM circuit 310 utilizes a comparator 304A that is configured to compare the analog voltage signal provided to the positive terminal of comparator 304A by MUX 302 against a reference signal provided to the negative terminal of comparator 304A by +Vcc. If the analog voltage value provided to the positive terminal is greater than the analog voltage value provided to the negative terminal then comparator 304A outputs PWM signal 306 which is a “high” digital signal having a binary value of “1”. If the analog voltage value provided to the positive terminal is less than the analog voltage value provided to the negative terminal then comparator 304A outputs PWM signal 306 which is a “low” digital signal having a binary value of “0”.

In one illustrative embodiment and as indicated above, jittery clock 316 includes a resistor-capacitor (“RC”) circuit and a comparator 304B, wherein the RC circuit and comparator 304B cooperate to provide clock signal 307. Similarly, PWM circuit 310 also includes a resistor-capacitor (“RC”) circuit, a comparator 304A and a transistor (Q1) wherein the RC circuit and comparator 304A cooperate to provide PWM signal 306, while the RC circuit and transistor (Q1) cooperate to provide clock signal 308. Thus, clock signal 307 is periodically generated by comparator 304B triggered by a capacitor discharge (C2) wherein the discharge rate corresponds to the time constant of the RC circuit of jittery clock 316. Because capacitor tolerances are wide and capacitance varies with temperature, clock signal 307 is jittery: i.e. its periodicity is dithered. Likewise, clock signal 308 is periodically generated by transistor (Q1) triggered by a capacitor discharge (C1) wherein the discharge rate corresponds to the time constant of the RC circuit of PWM circuit 310. Equally, the exemplary clock and signal output functions of PWM circuit 310 will also vary greatly with temperature, because comparator 304A triggers on a capacitor charge (C1). In the various illustrative embodiments of the present disclosure, the average frequency of clock signal 307 and clock signal 308 are each well below various frequencies currently in use for RF communications. As such, clock signal 307 and clock signal 308 each occur at a frequency that is below a predetermined threshold frequency such that electromagnetic interference (“EMI”) does not interfere with operation of device under test 128 that may be positioned adjacent the low EMI voltage measurement system.

In one illustrative embodiment, PWM circuit 310 may be configured to provide temperature compensation data to, for example, computing device 108 by including calibration voltage data within each digital transmission frame. The temperature compensation data is provided, in part, by the second input 314. As described above, first input 312 includes one or more measured analog voltage signals with each signal corresponding to an analog voltage value and second input 314 includes one or more analog reference voltage signals with each signal corresponding to an analog voltage value. In the illustrative embodiment of FIG. 3, three of the exemplary MUX inputs (second input 314) are tied to three different reference voltages and will be PWM converted in the same manner as first input 312 which are unknown voltages to be measured (VIN1, . . . , VIN5). In one illustrative embodiment, the unknown voltages are measured via a conventional antenna (not shown) configured to receive electromagnetic waves in the form of radio frequency (RF) signals corresponding to a particular analog or DC voltage value. Temperature-stable, precision voltage references are available from many integrated circuit (IC) manufacturers and may be procured at a relatively modest cost.

In the illustrative embodiment of FIG. 3, logic circuit 313 includes at least two NOR gates 322 and at least two inverters 324 such that logic circuit 313 provides logic to create frame separators within a digital transmission frame. Stated another way, logic circuit 313 is configured to periodically turn-off FOT 315. In various embodiments of the present disclosure, the frame separator logic provided by logic circuit 313 enables receiver module 106 to determine the position of the various pulses that comprise a digital transmission frame. Additionally, in the illustrative embodiment of FIG. 3 and as described above, a 4-bit counter such as counter 318 provides the input selection logic to MUX 302 and is therefore used in the frame separator logic. As provided in the illustrative embodiment of FIG. 2A, jittery clock 316 may be coupled to counter 318 such that clock signal 307 causes counter 318 to output a discrete signal having 4-bits wherein at least 3-bits function as input selection logic 320. The 3-bits of input selection logic 320 are provided as inputs to MUX 302 which in turn causes MUX 302 to output an analog voltage signal corresponding to a particular input pin of first input 312 or second input 314. Likewise, as provided in the illustrative embodiment of FIG. 2B, PWM circuit 310 may be coupled to counter 318 such that clock signal 308 causes counter 318 to output a discrete signal having 4-bits wherein at least 3-bits function as input selection logic 320.

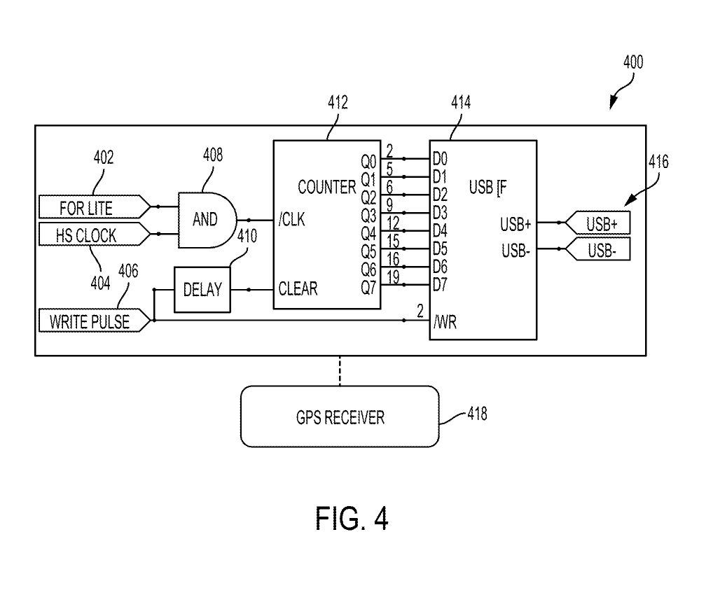

FIG. 4 shows an exemplary receiver module schematic. Receiver schematic 400 includes fiber-optic receiver input 402 (hereinafter “FOR input 402”), high speed (“HS”) clock 404, write pulse 406, AND gate 408, delay module 410, counter 412, USB transceiver 414, USB transceiver output 416, and GPS receiver 418. In the illustrative embodiment of FIG. 4, receiver schematic 400 provides a realization of a receiver module 106 and may also be referred to as receiver board 400 or receiver circuit 400. An optical signal is converted to an electrical pulse via a fiber-optic receiver (FOR). The output of the FOR is provided to FOR input 402 and may be designated a signal named “FOR LITE”. In the various illustrative embodiments of the present disclosure, the “high” and “low” state of the digital signal provided to FOR input 402 corresponds to the gated output of FOT 315. Accordingly, the digital signals provided to FOR input 402 may include one or more bits or bytes which indicate a digitized-voltage corresponding to the analog voltage value measured by first input 312 and/or second input 314. A fiber-optic cable may be utilized to provide a signal path which carries the digitized information (an optical signal) from FOT 315 within transmitter module 104 to the exemplary FOR within receiver module 106.

In one illustrative embodiment and as is known in the art, the pulse width of the FOR LITE signal may be measured with a counter strobe or operated by a high-speed clock such as HS clock 404 in cooperation with AND gate 408. One or more pulse counts (digital signals) may be temporarily stored within counter 412 prior to being provided to USB transceiver 414. Periodically, a WRITE PULSE triggers writing of these pulse counts to USB transceiver 414 and USB transceiver 414 subsequently provides, via output 416, a digital data stream or transmission frame to, for example, computing device 108. After the pulse counts are written to the USB transceiver, delay module 410 provides a signal to counter 412 which causes counter 412 to reset thereby clearing the individual pulses or digital signals temporarily stored in counter 412. Thus, delay module 410 assures that counter 410 is reset after the pulse counts equal a predetermined threshold pulse count and are subsequently latched into USB transceiver 414. In one embodiment, one or more NOR gates as well as an additional counter device may be used to determine the frequency that pulse counts are transmitted to USB transceiver 414. Additionally, one or more flip-flops may be used to assist in controlling signal timing and/or the reset function of pulse-width counter 412.

In one illustrative embodiment, receiver schematic 400 is configured to convert the optical light pulses into a personal computer (“PC”)-compatible data format and then transmits or streams this data to a PC via an industry standard PC interface like USB or RS232. In one illustrative embodiment, a computing device 108 may be used for recording the digitized-voltages to one or more non-volatile memory modules such as memory 126. However, in an alternate embodiment, other exemplary computing devices such as Smart phones, Personal Digital Assistant (“PDA”), or a custom-built recorder may include the above mentioned data recording functionality. Likewise, if the other exemplary computing devices include a display, then these devices may also be used to monitor and display the measured analog voltages in real-time. In various illustrative embodiments of the present disclosure, receiver schematic 400 utilizes the commonly known Universal Serial Bus (USB) protocol for communications and power via electronic coupling to a personal computer such as computing device 108.

In the illustrative embodiment of FIG. 4, GPS receiver 418 provides a universal time-stamp for the digitized-voltages such that analog voltage signal data measured via first input 312 and second input 314 may be synchronized. In one aspect of this illustrative embodiment, receiver schematic 400 may include a GPS interface (not shown) for decoding time-synch information from GPS receiver 418. In a variant of this aspect, an additional exemplary function of GPS receiver 418 is to provide a common universal time wherein the time is provided by an orbiting global positioning satellite. Reliable commercial off-the-shelf (“COTS”) GPS receivers with robust universal time stamping functionality are available from one or more receiver manufacturers and may be procured at a relatively modest cost. In one embodiment, the GPS interface may be configured to stream the state of two digital output signals to USB transceiver 414. USB transceiver 414 may be configured to interleave the pulse-width counts and GPS signals onto the USB digital data stream transmitted from output 416. The digital data stream may consist of a two-byte sequence: 1) a pulse-count byte followed by; 2) a byte with the GPS signals which correspond to GPS time-synching data. Accordingly, receiver schematic 400 may include one or more pull-up resistors which modify the two most significant bits of the digital data stream, and because of this, receiver schematic 400 ensures that the pulse-count byte never exceeds a corresponding decimal value of 128, and the GPS-signal byte is always greater than a corresponding decimal value of 191.

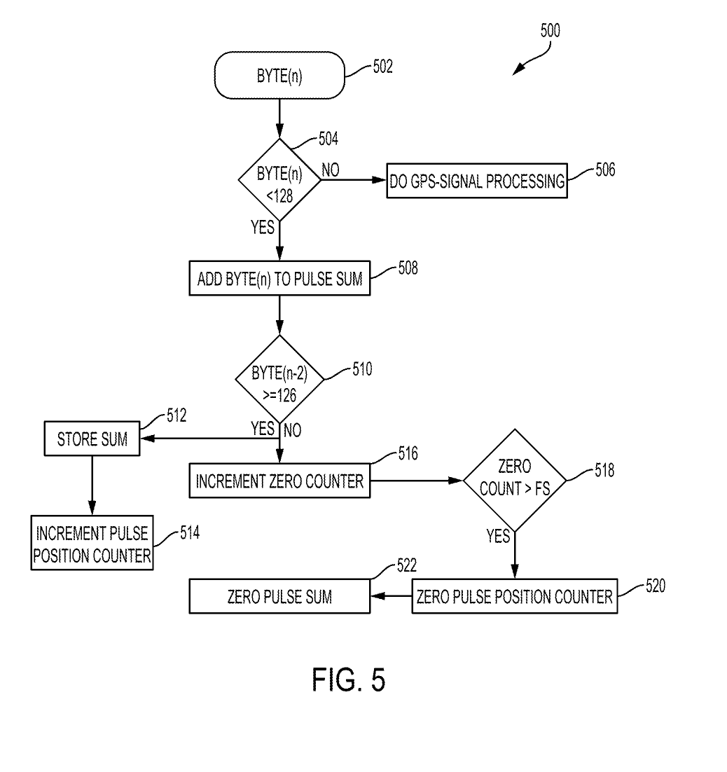

FIG. 5 shows an exemplary data stream unpacking process. Process 500 may be used to convert an exemplary digital data stream into one or more measured analog voltage values. Process 500 begins at step 502 wherein a digital data stream or digital transmission frame includes one or more bytes having a particular decimal valve. At step 502 the process identifies the pulse-width bytes and the GPS-signal bytes. As indicated above, pulse-width bytes are less than a corresponding decimal value of 128 and GPS-signal bytes are greater than a corresponding decimal value of 191. At step 504 the process determines if the pulse-width byte is less than a decimal value of 128. If the pulse-width byte is not less than 128 then the process advances to step 506 and adds the GPS signal bytes to an exemplary USB digital data stream transmitted from output 416. If the pulse-width byte is less than 128 then the process advances to step 508 wherein the process sums the pulse-width bytes to yield the total pulse count for each PWM signal. In various embodiments of the present disclosure, one or more digital pulses are separated by pulse-count bytes less than 127 and digital transmission frames of 12 pulses are separated by contiguous sequences of zero pulse-counts.

At step 510 the process subtracts 2 from the total pulse count for each PWM signal and determines if the total pulse count is greater than or equal to a decimal value of 126. If the result of the decision block at step 510 is “Yes” the process advances to step 512 and the total pulse count is stored in, for example, a memory module within computing device 108. After the total pulse count is stored the process advances to step 514 wherein the process increments the pulse position counter. If the result of the decision block at step 510 is “No” the process advances to step 516 wherein the process increments the zero counter. After incrementing the zero counter the process advances to step 518 wherein the process determines if the zero count is greater than frame sync (“FS”). If the result of the decision block at step 518 is “Yes” the process advances to step 520 and zero's or clears the pulse position counter. After zeroing/clearing the pulse position counter the process advances to step 522 and zero's/resets the pulse sum.

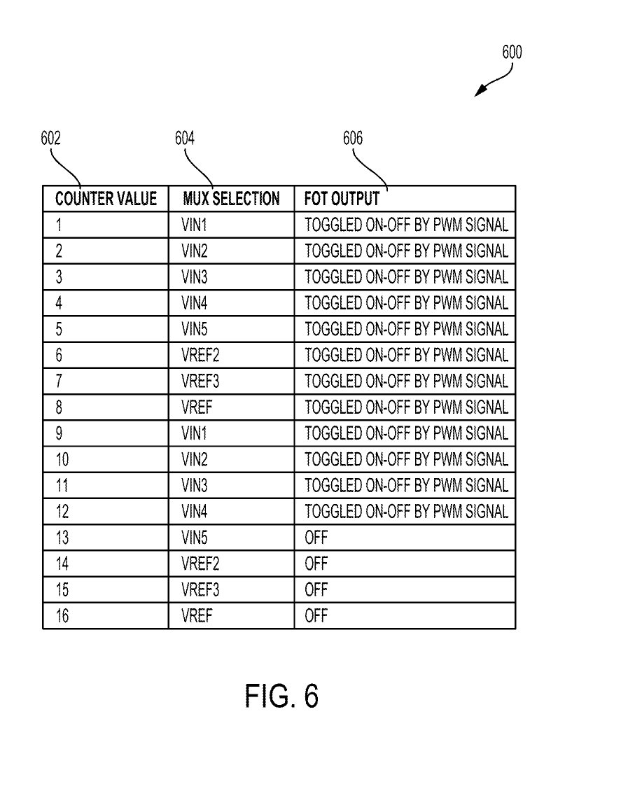

FIG. 6 shows a table providing an exemplary digital transmission frame. Table 600 includes counter value 602, MUX selection 604, and FOT output 606. In one embodiment, counter value 602 corresponds to input selection logic 320 provided by counter 318 wherein the counter values shown in table 600 are the equivalent decimal value of each binary signal sequentially provided by counter 318. For example, if counter 318 provides “001” as a binary input selection to MUX 302 then the corresponding analog voltage signal measured at input pin “VIN1” of first input 312 will be output by MUX 302. PWM circuit 310 will then perform PWM conversion on the analog voltage signal measured at VIN1 thereby producing PWM signal 306 which in turn will cause FOT 315 to be toggled “ON-OFF” by PWM signal 306. When in the “ON” state, FOT 315 will then transmit an optical signal including a first pulse count corresponding to a digitized voltage. The optical signal is ultimately provided to receiver circuit 400 and FOT 315 will toggle back to the “OFF” state in response to outputting the optical signal. In another example, if counter 318 provides “010” as a binary input selection to MUX 302 then the corresponding analog voltage signal measured at input pin “VIN2” of first input 312 will be output by MUX 302. PWM circuit 310 will once again perform PWM conversion but this time it will be on the analog voltage signal measured at VIN2 thereby producing a second PWM signal 306. The second PWM signal 306 will also cause FOT 315 to be toggled “ON-OFF”. The above process is repeated for all 16 frames shown in table 600 to produce an exemplary digital transmission frame.

In one illustrative embodiment, the transmission frame of Table 1 tabularizes the final output of FOT 315 of transmitter schematic 300. Within Table 1, the sixth, seventh, and eighth pulses correspond to the known reference analog voltage signals discussed above. In one illustrative embodiment, these reference pulse counts may be used to curve-fit a transfer function from pulse count to measured voltage for the digital transmission frame. In one aspect of this embodiment, both third-order polynomials and exponential curve-fits work well for accomplishing the curve-fit. Moreover, in addition to the recording software discussed above, one or more software applications may be developed to monitor the digital transmission frame and to curve-fit a particular transfer function in order to convert the pulse counts of the digital transmission frame to the corresponding measured analog voltage signals.

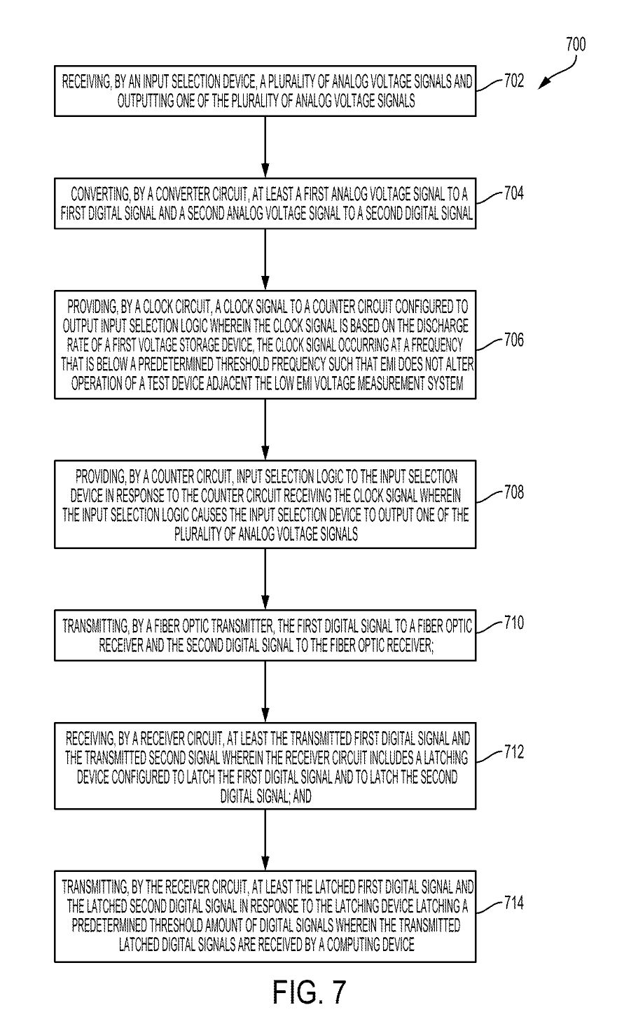

FIG. 7 shows a flow diagram of an exemplary method of the low EMI voltage measurement system of FIGS. 1-4. At step 702 method 700 begins by receiving, by an input selection device such as MUX 302, a plurality of analog voltage signals and outputting one of the plurality of analog voltage signals. Method 700 then proceeds to step 704 wherein the step includes converting, by a converter circuit such as PWM circuit 310, at least a first analog voltage signal to a first digital signal and a second analog voltage signal to a second digital signal. At step 706 method 700 provides, by a clock circuit such as jitter clock 316, clock signal 307 to, for example, a counter circuit such as counter circuit 318 that is configured to output input selection logic 320 wherein clock signal 307 is based on the discharge rate of a first voltage storage device (capacitor C2 of FIG. 3), clock signal 307 occurring at a frequency that is below a predetermined threshold frequency such that EMI does not alter operation of a device under test 128 which may be located adjacent the low EMI voltage measurement system. At step 708 method 700 provides, by counter circuit 318, input selection logic 320 to the input selection device or MUX 302, in response to counter circuit 318 receiving clock signal 307 wherein input selection logic 320 causes the input selection device to output one of the plurality of analog voltage signals. Method 700 then proceeds to step 710 wherein the step includes transmitting, by a fiber optic transmitter such as FOT 315, the first digital signal to a fiber optic receiver and the second digital signal to the fiber optic receiver. At step 712 method 700 receives, by a receiver circuit such as receiver circuit 400, at least the transmitted first digital signal and the transmitted second signal wherein receiver circuit 400 includes a latching device such as USB transceiver 414 that is configured to latch the first digital signal and to latch the second digital signal. Method 700 then proceeds to step 714 wherein the step includes transmitting, by receiver circuit 400, at least the latched first digital signal and the latched second digital signal in response to the latching device latching a predetermined threshold amount of digital signals wherein the transmitted latched digital signals are received by a computing device such as computing device 108.

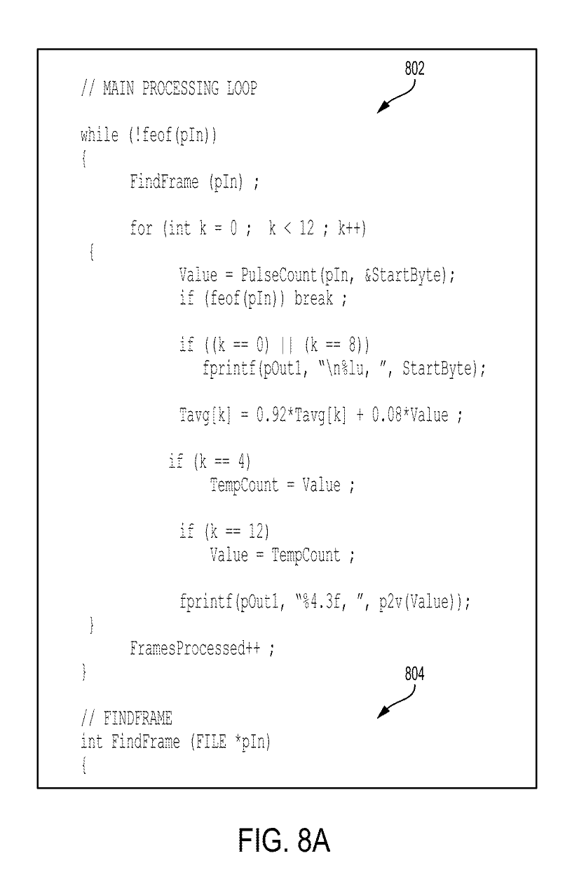

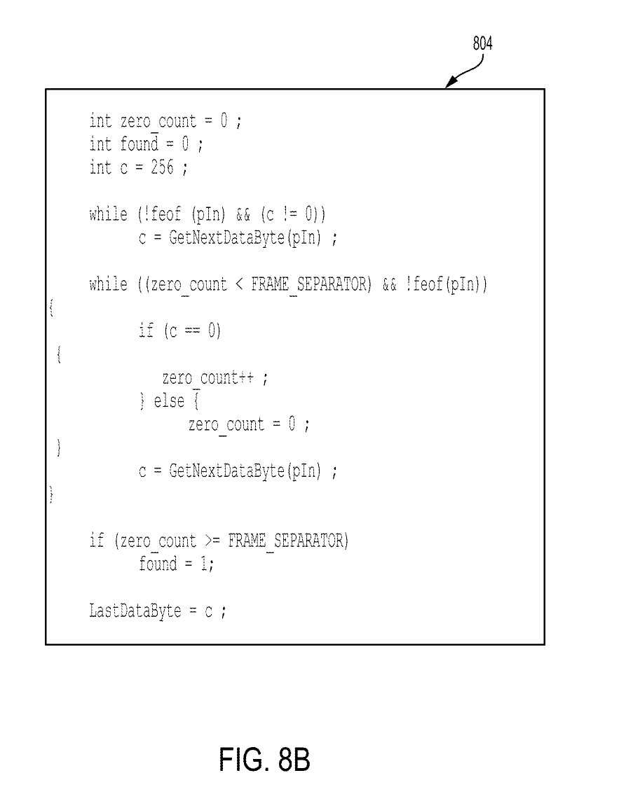

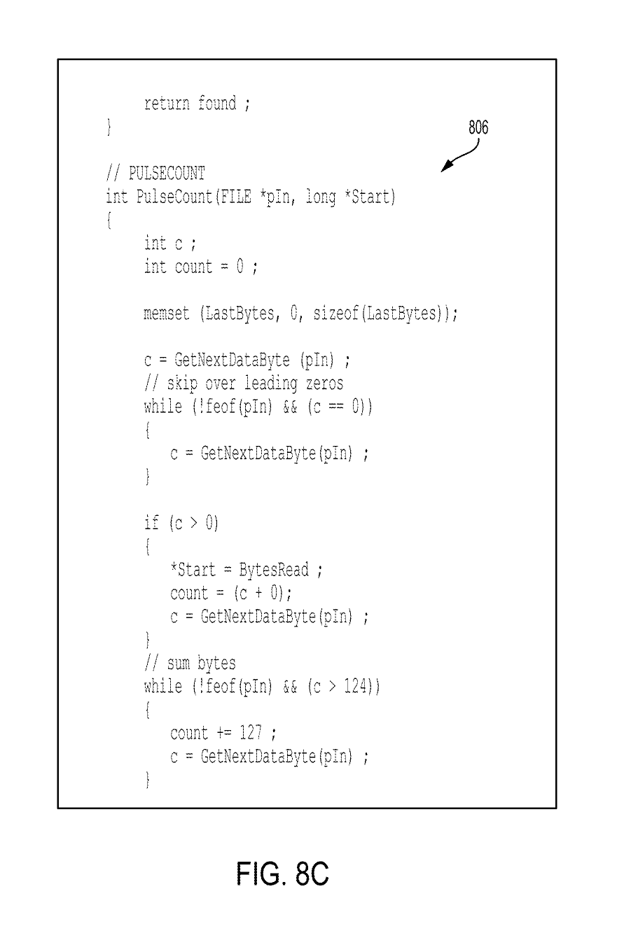

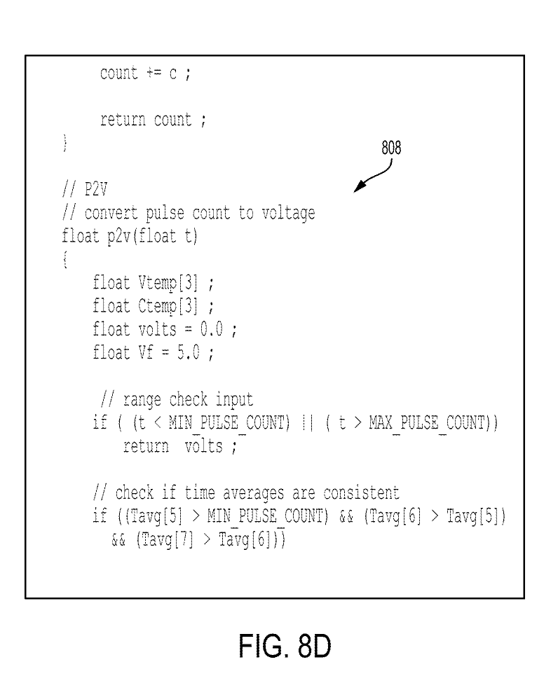

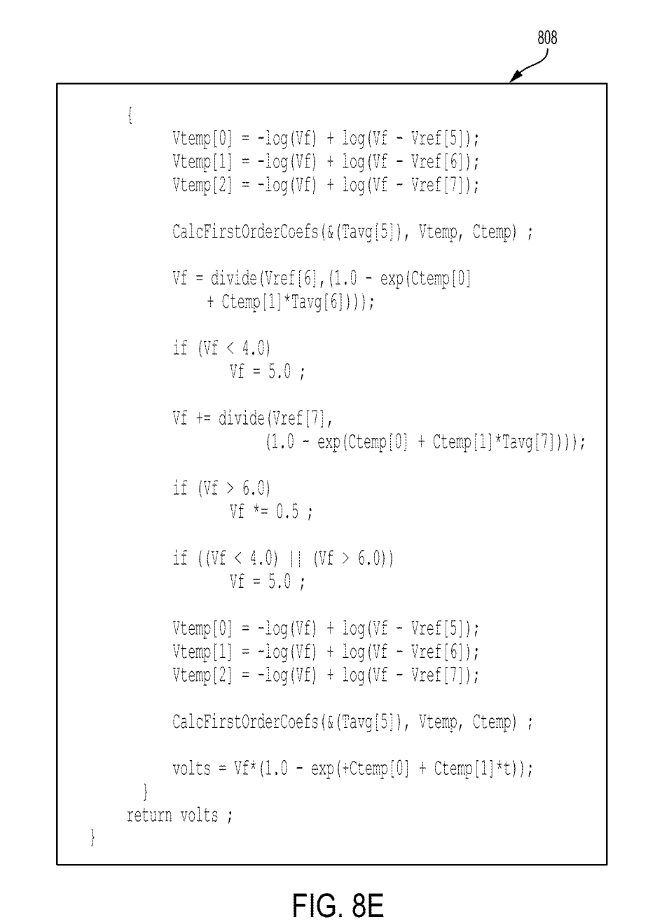

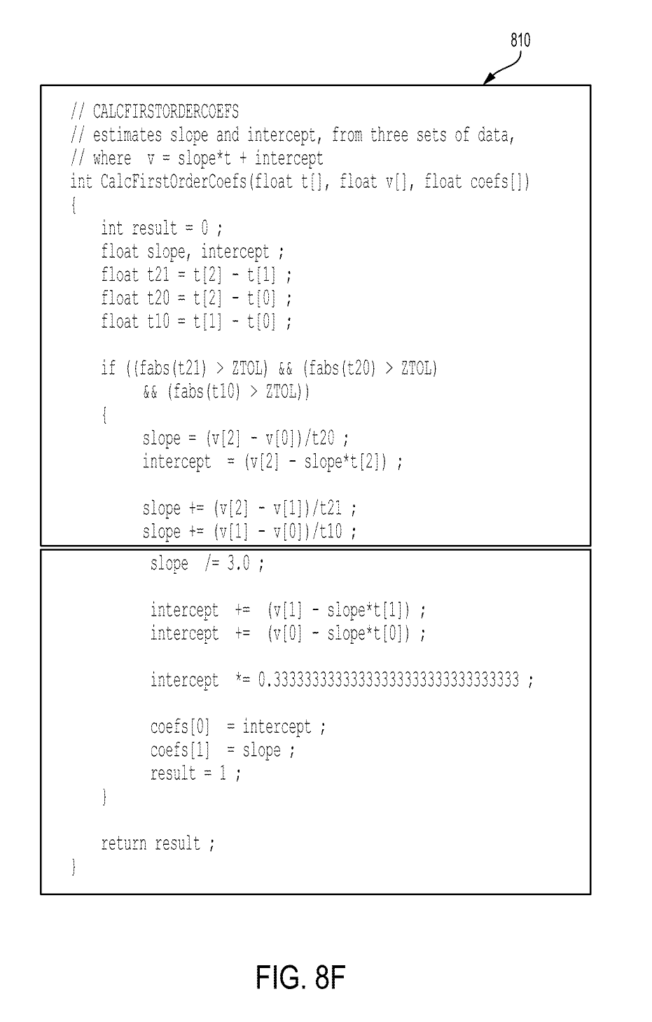

FIGS. 8A, 8B, 8C, 8D, 8E, and 8F show source code which may be used to develop one or more software applications or software programs to accomplish one or more functions of the low EMI voltage measurement system of the illustrative embodiments of FIGS. 1-7. FIG. 8A shows main processing loop 802 and initial lines of code which corresponds to the subroutine for findframe 804. FIG. 8B shows the remaining code for subroutine findframe 804. FIG. 8C shows a majority of the source code for subroutine pulse count 806. FIG. 8D shows the initial portion of the code that corresponds to the subroutine for pulse count to voltage conversion 808. With regard to subroutine 808, for a single voltage measurement the FOT 315 on-time corresponds to the measured analog voltage signals and the RC-time constant for the comparator circuit shown in FIG. 3 (PWM circuit 310). Resistor R1 and capacitor C1 control this time constant. The time that the light is on (FOT 315) is a function of R1, C1, temperature, and magnitude of the measured voltage signal. The time that the light is on corresponds to the time an RC circuit takes to discharge or progress through an exponential decay. In the illustrative embodiment of FIGS. 8D, 8E, and 8F, function p2V(t) returns the measured voltage. The input “t” is the FOT 315 light-on time. Subroutine 810 provides source for initiating a function which calculates first order coefficients. Thus subroutine 810 calculates the slope and intercept of a line based on three X-Y data points. This function is used by p2v. Likewise, in subroutine 806, the function PulseCount returns the total time (in pulsecounts) that the FOT 305 light is ON for a single pulse. For example, a pulse count of 600 and a sample clock rate of 10 MHz indicate that the FOT 315 light was on for 60 microseconds. Similarly, in subroutine 804, the function FindFrame parses a data file advancing the file pointer to the start of the next frame of bytes corresponding to analog voltage measurements. Thus, the main overall function of the source code is to at least parse a data file corresponding to a digital data transmission of voltage measurement bytes, converting the bytes into voltage measurements, and displaying and/or printing the voltage measurements.

In the foregoing specification, specific embodiments of the present disclosure have been described. However, one of ordinary skill in the art will appreciate that various modifications and changes can be made without departing from the scope of the disclosure as set forth in the claims below. Accordingly, the specification and figures are to be regarded in an illustrative rather than a restrictive sense, and all such modifications are intended to be included within the scope of disclosure. The benefits, advantages, solutions to problems, and any element(s) that may cause any benefit, advantage, or solution to occur or become more pronounced are not to be construed as critical, required, or essential features or elements of any or all the claims. The disclosure is defined solely by the appended claims including any amendments made during the pendency of this application and all equivalents of those claims as issued. Although the invention has been described in detail with reference to certain preferred embodiments, variations and modifications exist within the spirit and scope of the invention as described and defined in the following claims.

1. A low electromagnetic interference (“EMI”) voltage measurement system comprising:
an input selection device configured to receive a plurality of analog voltage signals and output one of the plurality of analog voltage signals;
a converter circuit coupled to the input selection device, the converter circuit configured to convert at least a first analog voltage signal to a first digital signal and convert a second analog voltage signal to a second digital signal;
a clock circuit configured to output a clock signal to cause the input selection device to output one of the plurality of analog voltage signals;
a counter circuit coupled to the input selection device, the counter circuit configured to receive the clock signal and to provide input selection logic to the input selection device in response to receiving the clock signal;
a fiber optic transmitter coupled to the converter circuit and configured to transmit the first digital signal to a fiber optic receiver and transmit the second digital signal to the fiber optic receiver; and
a receiver circuit configured to receive at least the transmitted first digital signal and receive the transmitted second digital signal, the receiver circuit including a latching device configured to latch the first digital signal and to latch the second digital signal and in response to latching a predetermined threshold amount of digital signals, the receiver circuit transmits the latched digital signals to a computing device;
wherein the clock signal is based on the discharge rate of a first voltage storage device, the clock signal occurring at a frequency that is below a predetermined threshold frequency such that EMI does not alter operation of a device under test adjacent the low EMI voltage measurement system.

2. The low EMI voltage measurement system of claim 1, wherein the receiver circuit includes a counter device and a transceiver, wherein the counter device and the transceiver cooperate to latch one or more transmitted digital signals.

3. The low EMI voltage measurement system of claim 1, wherein the converter circuit includes a second voltage storage device configured to discharge a first analog voltage signal and the converter circuit is further configured to output a digital signal based on at least the first analog voltage signal being greater than a second analog voltage signal.

4. The low EMI voltage measurement system of claim 2, wherein each digital signal corresponds to an analog voltage signal and indicates an analog voltage value.

5. The low EMI voltage measurement system of claim 2, wherein in response to latching a predetermined amount of digital signals a write pulse causes at least one of the receiver circuit to transmit the latched digital signals to a computing device and the counter device to reset.

6. The low EMI voltage measurement system of claim 1, further including a logic circuit coupled to the converter circuit and coupled to the fiber optic transmitter, the logic circuit configured to at least invert the first digital signal and invert the second digital signal.

7. The low EMI voltage measurement system of claim 4, further including a global position system (“GPS”) receiver coupled to the receiver circuit, the GPS receiver configured to provide universal-time-stamping of the received transmitted digital signals such that receipt of analog voltage values corresponding to the digital signals are synchronize.

8. The low EMI voltage measurement system of claim 1, wherein the low EMI voltage measurement system is operable within a temperature range of −20° C. to +60° C., includes a voltage measurement accuracy of less than 10 mV, and operates based on a direct current (DC) supply voltage ranging from 5 VDC to 12 VDC.

9. The low EMI voltage measurement system of claim 5, wherein the receiver circuit transmits, to the computing device, a digital data stream of a predetermined byte size, the digital data stream including at least a pulse-width byte and a GPS signal byte wherein the pulse-width byte corresponds to a first decimal value and the GPS signal byte corresponds to a second decimal value that is greater than the first decimal value.

10. A method in a low electromagnetic interference (“EMI”) voltage measurement system comprising:
receiving, by an input selection device, a plurality of analog voltage signals and outputting one of the plurality of analog voltage signals;
converting, by a converter circuit, at least a first analog voltage signal to a first digital signal and a second analog voltage signal to a second digital signal;
providing, by a clock circuit, a clock signal to a counter circuit configured to output input selection logic wherein the clock signal is based on the discharge rate of a first voltage storage device, the clock signal occurring at a frequency that is below a predetermined threshold frequency such that EMI does not alter operation of a device under test adjacent the low EMI voltage measurement system;
providing, by a counter circuit, input selection logic to the input selection device in response to the counter circuit receiving the clock signal wherein the input selection logic causes the input selection device to output one of the plurality of analog voltage signals;
transmitting, by a fiber optic transmitter, the first digital signal to a fiber optic receiver and the second digital signal to the fiber optic receiver;
receiving, by a receiver circuit, at least the transmitted first digital signal and the transmitted second signal wherein the receiver circuit includes a latching device configured to latch the first digital signal and to latch the second digital signal; and
transmitting, by the receiver circuit, at least the latched first digital signal and the latched second digital signal in response to the latching device latching a predetermined threshold amount of digital signals wherein the transmitted latched digital signals are received by a computing device.

11. The method of claim 10, wherein each digital signal corresponds to an analog voltage signal and indicates an analog voltage value.

12. The method of claim 11, wherein the computing device includes recording software and at least one memory module, and the method further includes, recording, by the recording software, one or more digital signals corresponding to one or more analog voltage signals, and in response to recording, storing, by the memory module, the one or more digital signals.

13. The method of claim 11, further including, providing, by a global positioning system (“GPS”) receiver, a universal-time-stamp of the received transmitted digital signals such that receipt, by the low EMI voltage measurement system, of analog voltage values corresponding to the digital signals are synchronized.

14. The method of claim 10, wherein the low EMI voltage measurement system is operable within a temperature range of −20° C. to +60° C., includes a voltage measurement accuracy of less than 1 OmV, and operates based on a direct current (DC) supply voltage ranging from 5 VDC to 12 VDC.

15. The method of claim 10, wherein the converter circuit includes a second voltage storage device and the method further includes, discharging, by the second voltage storage device, a first analog voltage signal such that the converter circuit outputs a digital signal based on at least the first analog voltage signal being greater than a second analog voltage signal.

16. A low electromagnetic interference (“EMI”) voltage measurement system comprising:
an input selection device configured to receive a plurality of analog voltage signals and output one of the plurality of analog voltage signals;
a transmitter module coupled to the input selection device, the transmitter module configured to convert an analog voltage signal to a digital signal and transmit the digital signal;
a receiver module coupled to the transmitter module and configured to receive the digital signal, the receiver module including a latching device configured to latch the digital signal and in response to latching a predetermined threshold amount of digital signals, the receiver module transmits the latched digital signals to a computing device; and
a clock circuit coupled to the input selection device and configured to output a clock signal to cause the input selection device to output one of the plurality of analog voltage signals, wherein the clock signal occurs at a frequency that is below a predetermined threshold frequency such that EMI does not alter operation of a device under test adjacent the low EMI voltage measurement system.

17. The low EMI voltage measurement system of claim 16, further including a delay module configured to delay the clock signal such that the input selection device receives the clock signal at a first time period and the transmitter module receives the clock signal at a second time period.

18. The low EMI voltage measurement system of claim 17, wherein the clock signal is based on the discharge rate of a voltage storage device and wherein the clock circuit is a dithered clock circuit such that the periodicity of the clock signal is dithered.

19. The low EMI voltage measurement system of claim 18, further including a counter circuit coupled to the input selection device, the counter circuit providing input selection logic to the input selection device in response to receiving the clock signal.

20. The low EMI voltage measurement system of claim 16, wherein the receiver module includes a counter device and a transceiver, wherein the counter device and the transceiver cooperate to latch one or more digital signals.

21. The low EMI voltage measurement system of claim 20, further including a global positioning system (“GPS”) receiver coupled to the receiver module, the GPS receiver providing a universal-time-stamp of the one or more digital signals wherein the one or more digital signals correspond to an analog voltage signal and indicates an analog voltage value.

22. A low electromagnetic interference (EMI) voltage measurement system comprising:
an input selection device configured to receive a plurality of analog voltage signals and output one of the plurality of analog voltage signals;
a converter circuit coupled to the input selection device, the converter circuit configured to convert at least a first analog voltage signal to a first digital signal, convert a second analog voltage signal to a second digital signal, and output a clock signal;
a counter circuit coupled to the input selection device, the counter circuit configured to receive the clock signal and to provide input selection logic to the input selection device in response to receiving the clock signal;
a logic circuit coupled to the converter circuit, the logic circuit configured to at least invert the first digital signal and invert the second digital signal;
a fiber optic transmitter coupled to the logic circuit and configured to transmit the first digital signal to a fiber optic receiver and transmit the second digital signal to the fiber optic receiver; and
a receiver circuit configured to receive at least the transmitted first digital signal and receive the transmitted second digital signal, the receiver circuit including a latching device configured to latch the first digital signal and to latch the second digital signal and in response to latching a predetermined amount of digital signals, the receiver circuit transmits the latched digital signals to a computing device;
wherein the clock signal is based on the discharge rate of a voltage storage device, the clock signal occurring at a frequency that is below a predetermined threshold frequency such that EMI does not alter operation of a device under test adjacent the low EMI voltage measurement system.

23. A method of configuring and operating a low electromagnetic interference (“EMI”) voltage measurement testing system in proximity with a device under test comprising:
providing a voltage testing system comprising a clock circuit;
providing, by the clock circuit, a clock signal to a counter circuit configured to output input selection logic wherein the clock signal is based on the discharge rate of a first voltage storage device, the clock signal occurring at a frequency that is below a threshold frequency;
providing an input selection device configured to receive a plurality of analog voltage signals and output one of the plurality of analog voltage signals;
providing a converter circuit coupled to the input selection device, the converter circuit configured to convert at least a first analog voltage signal to a first digital signal and convert a second analog voltage signal to a second digital signal;
providing a device under test having a receiver configured to operate in response to receiving a radio frequency (“RF”) signal;
positioning the voltage testing system in close proximity to the device under test;
determining, by an assessment module, a plurality of device under test electromagnetic interference (“EMI”) vulnerability characteristics comprising one or more operating signal frequencies of the device under test;
configuring the voltage testing system comprising configuring the clock circuit to operate at a frequency other than the one or more operating signal frequencies of the device under test
receiving, by the input selection device, a plurality of analog voltage signals and outputting one of the plurality of analog voltage signals;
converting, by the converter circuit, at least a first analog voltage signal to a first digital signal and a second analog voltage signal to a second digital signal;
providing, by a counter circuit, input selection logic to the input selection device in response to the counter circuit receiving the clock signal wherein the input selection logic causes the input selection device to output one of the plurality of analog voltage signals;
providing a fiber optic interface cable coupled to an optical output signal interface section of a transmitter of the voltage testing system and an optical input signal interface section of a receiver of the voltage testing system;
transmitting, by the fiber optic interface cable, the first digital signal to the optical input signal interface section of the receiver and the second digital signal to the optical input signal interface section of the receiver;
receiving, by the optical input signal interface section of the receiver, at least the transmitted first digital signal and the transmitted second signal wherein the receiver includes a latching device configured to latch the first digital signal and to latch the second digital signal; and
transmitting, by the receiver, at least the latched first digital signal and the latched second digital signal in response to the latching device latching a predetermined threshold amount of digital signals wherein the transmitted latched digital signals are received by a computing device; and
generating a plurality of outputs comprising one or more digital data bytes.
